(19) United States
(12) Patent Application Publication
(10) Pub. No.: US 2026/0282638 A1
(43) Pub. Date: Sep. 17, 2026

(54) DISPLAY DEVICE, MANUFACTURING METHOD OF THE SAME, AND ELECTRONIC DEVICE COMPRISING THE SAME

(71) Applicant: SAMSUNG DISPLAY CO., LTD., YONGIN-SI (KR)

(72) Inventors: Yong-Hoon KWON, YONGIN-SI (KR); WONBEOM LEE, YONGIN-SI (KR); TAEOH KIM, YONGIN-SI (KR); JEONGJIN PARK, YONGIN-SI (KR)

(21) Appl. No.: 19/382,638

(22) Filed: Nov. 7, 2025

(30) Foreign Application Priority Data
Mar. 12, 2025 (KR) 10-2025-0032111

(51) Int. Cl. H10H 29/853; H10H 29/01; H10H 29/49; H10H 29/85

(52) U.S. Cl. CPC H10H 29/853; H10H 29/012; H10H 29/0362; H10H 29/0364; H10H 29/49; H10H 29/8508

(57) ABSTRACT

A display device includes a display panel including a display area and a peripheral area including a pad portion. A substrate layer is disposed on the display panel. The substrate layer includes an end surface overlapping the peripheral area. A protective layer is disposed on the substrate layer. The protective layer includes a resin. The end surface of the substrate layer overlapping the peripheral area has an outermost edge protruding outwardly beyond remaining portions of the end surface. The outermost edge is disposed at a middle of the end surface of the substrate layer in a thickness direction of the display panel.

### CROSS-REFERENCE TO RELATED APPLICATIONS

This application claims priority under 35 U.S.C. §119 to Korean Patent Application No. 10-2025-0032111, filed on Mar. 12, 2025 in the Korean Intellectual Property Office, the disclosure of which is incorporated by reference in its entirety herein.

### 1. TECHNICAL FIELD

The present disclosure relates to a display device, a manufacturing method thereof, and an electronic device comprising the same.

### 2. DISCUSSION OF RELATED ART

A display device is a device for displaying images. Examples of display devices include a liquid crystal display (LCD), an organic light emitting diode (OLED), and the like. With the advancement of the information society, display devices are being applied to an increasing variety of electronic devices, such as mobile phones, navigation devices, digital cameras, electronic books, portable game machines, and various terminals.

### SUMMARY

Embodiments relate to a display device, a manufacturing method thereof, and an electronic device comprising the same, and are for preventing damage to a pad portion or a driving portion by laser when cutting a protective film disposed on a display panel.

According to an embodiment of the present disclosure, a display device includes a display panel including a display area and a peripheral area including a pad portion. A substrate layer is disposed on the display panel. The substrate layer includes an end surface overlapping the peripheral area. A protective layer is disposed on the substrate layer. The protective layer includes a resin. The end surface of the substrate layer overlapping the peripheral area has an outermost edge protruding outwardly beyond remaining portions of the end surface. The outermost edge is disposed at a middle of the end surface of the substrate layer in a thickness direction of the display panel.

In an embodiment, the end surface of the substrate layer may include an upper surface and a lower surface, the upper surface and the lower surface may meet each other at the outermost edge, and the upper surface and the lower surface may be curved surfaces.

In an embodiment, the curved surfaces of the upper surface and the lower surface may be concave.

In an embodiment, in the peripheral area, a top surface of the substrate layer connected to the upper surface may protrude beyond a bottom surface of the substrate layer connected to the lower surface.

In an embodiment, in the peripheral area, the outermost edge of the substrate layer may protrude beyond an end surface of the protective layer.

In an embodiment, in the end surface of the protective layer overlapping the peripheral area may be a curved surface.

In an embodiment, the display device may further include a damping layer disposed between the display panel and the substrate layer in the thickness direction of the display panel.

In an embodiment, in the peripheral area, the substrate layer and the protective layer may protrude beyond the damping layer.

In an embodiment, the display device may further include a first adhesive layer disposed between the display panel and the damping layer in the thickness direction of the display panel and a second adhesive layer disposed between the damping layer and the substrate layer in the thickness direction of the display panel.

According to an embodiment of the present disclosure, a manufacturing method of a display device includes preparing a display panel including a display area and a peripheral area including a pad portion, preparing an extended substrate layer having a first temporary film attached to a first surface and a second temporary film attached to a second surface opposite to the first surface, detaching a portion of the first temporary film, forming a first groove by cutting an exposed portion of the extended substrate layer in a thickness direction of the display device at a first position, forming a second groove by reattaching the first temporary film, cutting the first temporary film at a second position adjacent to the first position, removing a portion of the first temporary film that does not overlap the first position to expose a portion of the first surface, attaching the extended substrate layer on the display panel such that the display panel and the first surface face each other, removing the second temporary film and coating a resin layer on the second surface, forming a third groove by cutting the resin layer and the extended substrate layer at a third position adjacent to the first position, and removing a portion of the resin layer and a portion of the extended substrate layer and the first temporary film. The third position overlaps the first temporary film and the peripheral area.

In an embodiment, the pad portion may extend along a first direction in the peripheral area.

In an embodiment, the first groove, the second groove, and the third groove may extend in the first direction.

In an embodiment, a center of the second position and a center of the third position may be respectively spaced apart in opposite directions from a center of the first position.

In an embodiment, the second position may be closer to the display area than the third position.

In an embodiment, a separation distance between the center of the first position and the center of the third position may be in a range of about 1 μm to about 10 μm.

In an embodiment, a separation distance between the center of the first position and the center of the second position may be in a range of about 10 μm to about 50 μm.

In an embodiment, a depth of the first groove may be about 50% of a total thickness of the extended substrate layer.

In an embodiment, a depth of the second groove may be in a range of about 90% to about 100% of a total thickness of the first temporary film.

In an embodiment, a depth of the third groove may be a sum of a total thickness of the resin layer and about 50% of a total thickness of the extended substrate layer.

In an embodiment, the manufacturing method may further include cutting the extended substrate layer and the resin layer along an edge of the display panel.

According to an embodiment of the present disclosure, an electronic device includes a display device and a processor. The display device includes a display panel including a display area and a peripheral area including a pad portion. A substrate layer is disposed on the display panel. The substrate layer includes an end surface overlapping the peripheral area. A protective layer is disposed on the substrate layer. The protective layer includes a resin. The end surface of the substrate layer overlapping the peripheral area has an outermost edge protruding outwardly beyond remaining portions of the end surface. The outermost edge is disposed at a middle of the end surface of the substrate layer in a thickness direction of the display panel.

A display device, a manufacturing method thereof, and an electronic device comprising the same according to an embodiment can prevent damage to a pad portion or a driving portion by laser when cutting a protective film disposed on a display panel.

### BRIEF DESCRIPTION OF THE DRAWINGS

FIG. 1 is a perspective view of a display device according to an embodiment of the present disclosure.

FIG. 2 is a perspective view of a display device according to an embodiment of the present disclosure.

FIG. 3 is an exploded perspective view of a display device according to an embodiment of the present disclosure.

FIG. 4 is a cross-sectional view of a display device according to an embodiment of the present disclosure.

FIGS. 5-12 are cross-sectional views sequentially showing a manufacturing process of a display device according to embodiments of the present disclosure.

FIG. 13 is a block diagram of an electronic device according to an embodiment of the present disclosure.

FIG. 14 are schematic diagrams of electronic devices according to various embodiments of the present disclosure.

### DETAILED DESCRIPTION OF EMBODIMENTS

Hereinafter, various non-limiting embodiments of the present disclosure will be described in detail with reference to the accompanying drawings so that those skilled in the art can easily implement the present disclosure. The present disclosure may be implemented in various different forms and is not limited to the described embodiments.

To clearly describe the present disclosure, parts not related to the description are omitted, and the same reference numerals are assigned to the same or similar components throughout the specification.

In addition, since the size and thickness of each component shown in the drawings may be arbitrarily shown for convenience of description, embodiments of the present disclosure are not necessarily limited to what is shown in the drawings. In the drawings, the thicknesses may be enlarged to clearly express various layers and regions. In the drawings, for convenience of description, the thicknesses of some layers and regions may be exaggerated.

In addition, when a part such as a layer, film, region, plate, or the like is said to be "on" or "above" another part, this includes not only the case where it is "directly on" another part, but also the case where there is another part in between. Conversely, when a part is said to be "directly on" another part, it means that there is no other part in between. In addition, being "on" or "above" a reference part means being positioned above or below the reference part, and does not necessarily mean being positioned "on" or "above" in the direction opposite to gravity.

In addition, throughout the specification, when a part is said to "include" a certain component, this means that it may further include other components rather than excluding other components unless specifically stated to the contrary.

In addition, throughout the specification, when referring to "planar view," this means when the target part is viewed from above, and when referring to "cross-sectional view," this means when a cross-section obtained by vertically cutting the target part is viewed from the side.

In addition, throughout the specification, "about" or "approximately" may include within ± 30%, 20%, 10%, or 5% of the corresponding numerical range.

The present disclosure concerns a display device having a substrate layer including an end surface having an outermost edge protruding outwardly and disposed at a middle of the end surface in a thickness direction of the display panel. An upper surface and lower surface of the end surface meeting at the outermost edge are curved.

The outermost edge of the substrate layer permits cutting at a first position prior to cutting at a third position. Thus, the cutting at the third position does not cut an entire thickness of the substrate layer and the cutting means, such as a laser, may not reach the display panel.

The third position and the first position do not coincide with each other and there is a separation distance between centers of the third position and the first position. Accordingly, the laser may be further prevented from reaching the display panel.

A first temporary film may overlap the third position and may prevent the laser from reaching the display panel. Therefore, damage to the display panel by the laser, such as to a pad portion or a driving unit, may be prevented.

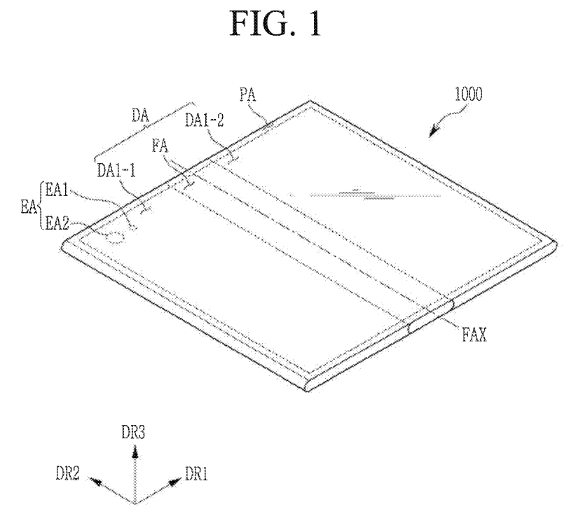

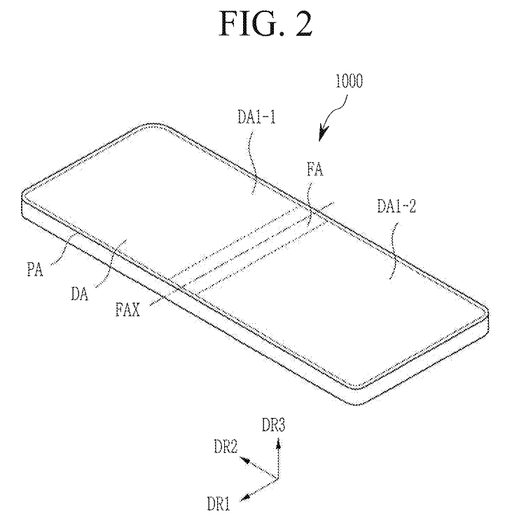

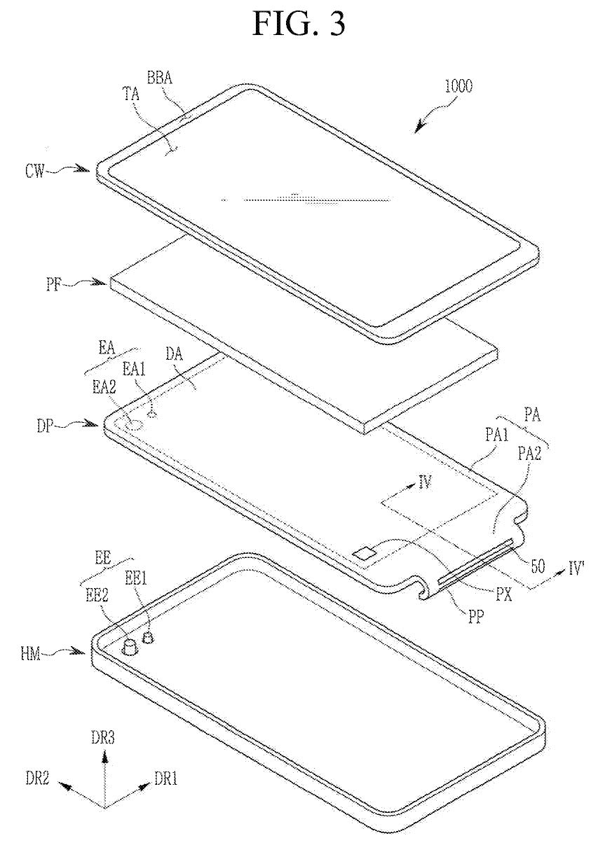

Hereinafter, a display device according to an embodiment will be described with reference to FIGS. 1-3. FIG. 1 is a perspective view of a display device according to an embodiment, FIG. 2 is a perspective view of a display device according to an embodiment, and FIG. 3 is an exploded perspective view of a display device according to an embodiment.

Referring to FIGS. 1-3, a display device 1000 according to an embodiment is a device for displaying at least one moving image and/or still image, and may be used in various electronic devices, such as a smart phone.

The display device 1000 may display an image towards a third direction DR3 on a display surface extending in a plane defined in a first direction DR1 and a second direction DR2 intersecting the first direction DR1. While an embodiment in FIG. 1 shows the first and second directions DR1, DR2 as being perpendicular to each other, embodiments of the present disclosure are not necessarily limited thereto. A display surface on which an image is displayed may correspond to a front surface of the display device 1000. The image may include a dynamic image as well as a still image.

In an embodiment, a front surface (e.g., an upper surface) and a rear surface (e.g., a lower surface) of each member are defined based on a direction in which an image is displayed. The front surface and the rear surface are opposite to each other in the third direction DR3, and a normal direction of each of the front surface and the rear surface may be parallel to the third direction DR3. A separation distance in the third direction DR3 between the front surface and the rear surface may correspond to a thickness of a display panel in the third direction DR3.

In an embodiment, the display device 1000 may be a foldable device. In this specification, a foldable device refers to a device capable of folding or otherwise deformed, and is used to include not only a device that is folded, but also a device that may have both a folded state and an unfolded state. In addition, folding typically includes a folding angle of about 180°, but is not necessarily limited thereto, and may be understood as being folded even when the folding angle is less than 180°, for example, 90° or more and less than 180°, or 120° or more and less than 180°. In addition, a folded state may include a state in which it is in a bent state even if complete folding is not achieved. For example, even if the folding angle is 90° or less, as long as the maximum folding angle is 90° or more, it may be expressed as being in a folded state to distinguish it from an unfolded state.

In an embodiment, the display device 1000 may include a display area DA, a component area EA, and a peripheral area PA. In an embodiment, the peripheral area PA may include a first peripheral area PA1 and a second peripheral area PA2.

A plurality of light emitting diodes and a plurality of pixel circuit units that generate and transmit light emitting currents to each of the plurality of light emitting diodes are formed in the display area DA (hereinafter also referred to as a main display area) and the component area EA. In an embodiment, one light emitting diode and one pixel circuit unit may be referred to as a pixel. In an embodiment, in the display area DA and the component area EA, one pixel circuit unit and one light emitting diode may be formed in a one-to-one relationship.

In an embodiment, the display area DA may include a first-first display area DA1-1, a first-second display area DA1-2, and a folding area FA. The first-first display area DA1-1 and the first-second display area DA1-2 may be positioned on left and right sides, respectively, with respect to (e.g., centered on) a folding axis FAX, and the folding area FA may be positioned between the first-first display area DA1-1 and the first-second display area DA1-2 (e.g., in the first direction DR1). In an embodiment, when folded outward with respect to the folding axis FAX, the first-first display area DA1-1 and the first-second display area DA1-2 are positioned on both sides in the third direction DR3 and may display images in both directions (e.g., on the front and rear surfaces). In addition, when folded inward with respect to the folding axis FAX, the first-first display area DA1-1 and the first-second display area DA1-2 may not be visible from the outside (e.g., the external environment).

A folding axis FAX according to an embodiment extends along the first direction DR1 or the second direction DR2 and may traverse the display area DA.

Although FIGS. 1 and 2 show one folding area FA, the display device 1000 according to an embodiment may include one or more folding areas FA. One or more folding areas FA may be folded around different axes, for example, an axis parallel to the first direction DR1 and/or an axis parallel to the second direction DR2, and the position and width of the folding area FA in the display device 1000 may be variously changed.

In an embodiment, the component area EA may include a first component area EA1 and a second component area EA2. The first component area EA1 and the second component area EA2 may be at least partially surrounded by the display area DA (e.g., in a plan view). Although the first component area EA1 and the second component area EA2 are shown as being spaced apart from each other, embodiments of the present disclosure are not necessarily limited thereto and the first and second component areas EA1, EA2 may be at least partially connected (e.g., directly connected) to each other. In an embodiment, the first component area EA1 and the second component area EA2 may be areas where optical elements (see EE in FIG. 3; hereinafter also referred to as components) using infrared rays, visible light, or sound are disposed below them.

The peripheral area PA is adjacent to the display area DA and may surround at least a portion of the display area DA (e.g., in a plan view). The peripheral area PA may not include any display pixels PX and an image may not be displayed in the peripheral area PA. In an embodiment, the peripheral area PA includes a first peripheral area PA1 and a second peripheral area PA2, and driving circuits or driving wires for driving the display area DA may be disposed in the second peripheral area PA2.

In an embodiment, with reference to FIG. 3, a schematic structure of the display device 1000 will be described. Although the display device 1000 of FIG. 3 is shown as a flat panel type, embodiments of the present disclosure are not necessarily limited thereto and the display device 1000 may also be a foldable display device as in embodiments of FIGS. 1 and 2.

The display device 1000 may include a cover window CW, a housing HM, a display panel DP, and an optical element EE. In an embodiment, the cover window CW and the housing HM may be combined to form an exterior of the display device 1000.

A protective film PF may be positioned between the display panel DP and the cover window CW (e.g., in the third direction DR3). The protective film PF is made of an optically transparent material and may protect the display panel DP.

The cover window CW may include an insulating panel. For example, in an embodiment the cover window CW may be composed of glass, plastic, or a combination thereof.

A front surface of the cover window CW may define a front surface of the display device 1000. The transmission area TA may be an optically transparent area. For example, in an embodiment the transmission area TA may be an area having a visible light transmittance (e.g., having a wavelength in a range of about 380 nm to about 780 nm) greater than or equal to about 90%.

The blocking area BBA may define a shape of the transmission area TA. The blocking area BBA is adjacent to the transmission area TA. In an embodiment, the blocking area BBA may surround the transmission area TA (e.g., in a plan view). The blocking area BBA may be an area having a relatively low light transmittance compared to the transmission area TA. The blocking area BBA may include an opaque material that blocks light. The blocking area BBA may have a predetermined color. In an embodiment, the blocking area BBA may be defined by a bezel layer provided separately from a transparent substrate that defines the transmission area TA, or by an ink layer formed by being inserted or colored in the transparent substrate.

The display panel DP may include display pixels PX that display images and a driving unit 50, and the display pixels PX are positioned in the display area DA and the component area EA. The display panel DP may include a front surface including the display area DA and the peripheral area PA. In an embodiment, the display area DA and the component area EA are areas where images are displayed by including the display pixels PX, and may also be areas where external input is detected by a touch sensor positioned above the display pixels PX in the third direction DR3.

The transmission area TA of the cover window CW may at least partially overlap with the display area DA and the component area EA of the display panel DP (e.g., in the third direction DR3). For example, the transmission area TA may overlap with the entire front surface of the display area DA and the component area EA, or may overlap with at least a portion of the display area DA and the component area EA. Accordingly, a user may view an image through the transmission area TA or provide external input based on the image. However, embodiments of the present disclosure are not necessarily limited thereto. For example, an area where an image is displayed and an area where external input is detected may be separated from each other.

The peripheral area PA of the display panel DP may at least partially overlap with the blocking area BBA of the cover window CW (e.g., in the third direction DR3). The peripheral area PA may be an area covered by the blocking area BBA. In an embodiment, the peripheral area PA may include a first peripheral area PA1 positioned outside the display area DA (e.g., in a plan view) and a second peripheral area PA2 including the driving unit 50, the pad portion PP, connection wiring, and a bending area. In FIG. 3, the first peripheral area PA1 is positioned on three sides of the display area DA, and the second peripheral area PA2 is positioned on the remaining one side of the display area DA. For example, the second peripheral area PA2 is positioned on the lower side in the second direction DR2. However, embodiments of the present disclosure are not necessarily limited thereto.

In an embodiment, a portion of the peripheral area PA of the display panel DP may be bent. In an embodiment, a portion of the peripheral area PA faces the rear surface of the display device 1000, so that a size (e.g., area in a plan view) of the blocking area BBA shown on the front surface of the display device 1000 may be reduced. In FIG. 3, the second peripheral area PA2 may be bent and positioned on the rear surface of the display area DA before assembly.

The driving unit 50 may be mounted on the second peripheral area PA2, and may be mounted on the bending area or positioned on one of two sides of the bending area. The driving unit 50 may be provided in a chip form.

The first component area EA1 may include a transmission part through which light and/or sound may pass and a display layer including a plurality of pixels. The transmission part is positioned between adjacent pixels and is composed of a layer through which light and/or sound may pass. Depending on the embodiment, a layer through which light does not pass, such as a light blocking member, may overlap with the first component area EA1. In an embodiment, the number of pixels per unit area (hereinafter also referred to as resolution) of pixels included in the display area DA (hereinafter also referred to as normal pixels) and the number of pixels per unit area of pixels included in the first component area EA1 (hereinafter also referred to as first component pixels) may be the same.

In an embodiment, the second component area EA2 includes an area composed of a transparent layer (hereinafter also referred to as a light transmission area) so that light may pass through, and the light transmission area does not have a conductive layer or a semiconductor layer positioned therein, and may have a structure that does not block light by including an opening where a layer including a light blocking material, for example, a pixel defining layer and/or a light blocking member, overlaps with a position corresponding to the second component area EA2. In an embodiment, the number of pixels per unit area of pixels included in the second component area EA2 (hereinafter also referred to as second component pixels) may be less than the number of pixels per unit area of normal pixels included in the display area DA. As a result, the resolution of the second component pixels may be lower than the resolution of the normal pixels.

The driving unit 50 is electrically connected to the display area DA and the component area EA and may transmit electrical signals to pixels in the display area DA and the component area EA. For example, the driving unit 50 may provide data signals to pixels PX disposed in the display area DA. Alternatively, the driving unit 50 may include a touch driving circuit and may be electrically connected to a touch sensor disposed in the display area DA and/or the component area EA. In addition, the driving unit 50 may include various circuits in addition to the above-described circuits or may be designed to provide various electrical signals to the display area DA.

In addition, in the display device 1000, a pad portion PP may be positioned at an end of the second peripheral area PA2, and may be electrically connected to a flexible printed circuit board (FPCB) including a driving chip through the pad portion PP. Here, the driving chip positioned on the flexible printed circuit board may include various driving circuits for driving the display device 1000 or connectors for power supply. In an embodiment, a rigid printed circuit board (PCB) may be used instead of the flexible printed circuit board.

The pad portion PP may extend along one side of the display panel DP in the second peripheral area PA2. In an embodiment shown in FIG. 3, the pad portion PP is shown extending in the first direction DR1.

The optical element EE may be disposed below the display panel DP (e.g., in a direction opposite to the third direction DR3). In an embodiment, the optical element EE may include a first optical element EE1 overlapping the first component area EA1 and a second optical element EE2 overlapping the second component area EA2.

The first optical element EE1 may be an electronic element using light or sound. For example, in an embodiment the first optical element EE1 may be a sensor that receives and uses light such as an infrared sensor, a sensor that outputs and detects light or sound to measure distance or recognize fingerprints, a small lamp that outputs light, or a speaker that outputs sound. In the case of electronic elements using light, it is natural that light of various wavelength bands such as visible light, infrared light, and ultraviolet light may be used.

In an embodiment, the second optical element EE2 may be at least one of a camera, an infrared camera (IR camera), a dot projector, an infrared illuminator (IR illuminator), and a time-of-flight sensor (ToF sensor).

The housing HM may be combined with the cover window CW. The cover window CW may be disposed on a front surface of the housing HM. The housing HM may be combined with the cover window CW to provide a predetermined accommodation space. The display panel DP and the optical element EE may be accommodated in a predetermined accommodation space provided between the housing HM and the cover window CW.

The housing HM may include a material having relatively high rigidity. For example, in an embodiment the housing HM may include glass, plastic, or metal, or may include a plurality of frames and/or plates composed of a combination thereof. The housing HM may stably protect the components of the display device 1000 accommodated in the internal space from external impact.

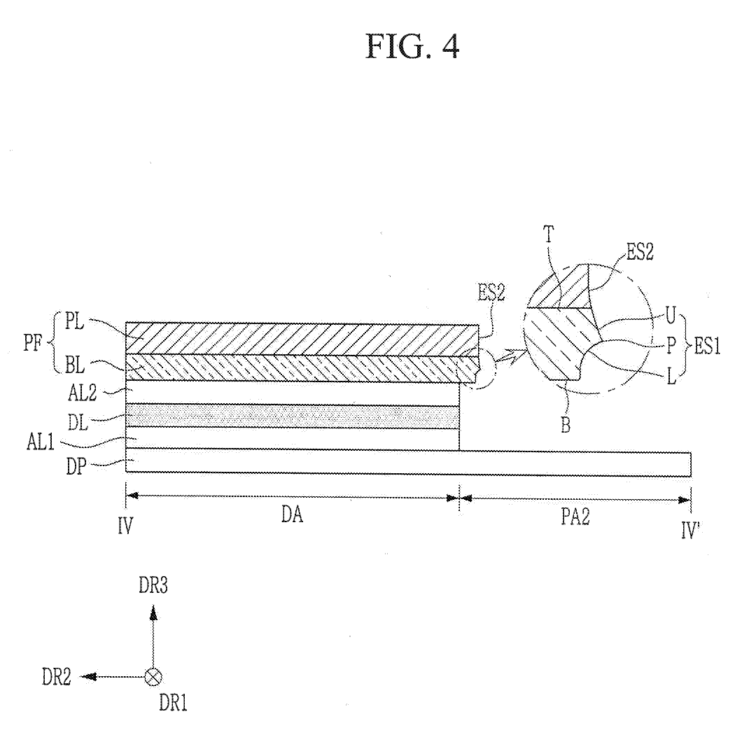

Referring to FIG. 4, a protective film PF of a display device according to an embodiment will be described. FIG. 4 is a cross-sectional view taken along VI-VI' of FIG. 3.

Referring to FIG. 4, the display panel DP may include a display area DA and a second peripheral area PA2. In an embodiment, the display panel DP may extend in a first direction DR1 and a second direction DR2, and the second peripheral area PA2 may be positioned at one edge of the display panel DP, such as a lower edge in the second direction DR2 in a plan view. A stacking direction may be a third direction DR3 perpendicular to the first direction DR1 and the second direction DR2 and may be a thickness direction of the display panel.

A protective film PF may be positioned on the display panel DP. The protective film PF may protect the display panel DP from external impact. In an embodiment, the protective film PF may include a substrate layer BL and a protective layer PL.

A substrate layer BL may be positioned on the display panel DP. The substrate layer BL may include a transparent material. The substrate layer BL may include glass or a polymer film. For example, in an embodiment the substrate layer BL may include polymer films such as polyethylene terephthalate (PET), polyimide (PI), triacetyl cellulose (TAC), and cyclic olefin polymer (COP). The substrate layer BL may be composed of a single layer or multiple layers. In an embodiment, a thickness of the substrate layer BL in the third direction DR3 may be in a range of about 20 μm to about 50 μm.

The substrate layer BL may include a top surface T (e.g., an uppermost surface in the third direction DR3) and a bottom surface B (e.g., a lowermost surface in the third direction DR3) opposing each other in the stacking direction (e.g., the third direction DR3. The bottom surface B may face the display panel DP, and the top surface T may face outwardly in the opposite direction. In addition, the substrate layer BL includes approximately four edges when viewed in a plan view, and an edge (e.g., an edge in a direction opposite to the second direction DR2) among the four edges that overlaps the second peripheral area PA2 may include a first end surface ES1. In an embodiment, the top surface T and the bottom surface B extend in a first direction DR1 and a second direction DR2, respectively, and the first end surface ES1 may extend in the first direction DR1.

In the second peripheral area PA2, the top surface T of the substrate layer BL may protrude beyond the bottom surface B. For example, in an embodiment the top surface T of the substrate layer BL may protrude in a range of about 1 μm to about 10 μm beyond the bottom surface B.

The first end surface ES1 may include an outermost edge P, and the outermost edge P protrudes most outwardly in a direction opposite to the second direction DR2 from the first end surface ES1. For example, the outermost edge P protrudes beyond all remaining portions of the end surface ES1 (e.g., in a direction opposite to the second direction DR2). The outermost edge P may extend in the first direction DR1 and may be positioned at a middle of the first end surface ES1 in the third direction DR3. For example, the outermost edge P may be positioned between the top surface T and the bottom surface B of the first end surface ES1 (e.g., in the third direction DR3). The middle of the first end surface ES1 may be a central portion in the third direction DR3 but may be spaced apart from an exact middle point of the first end surface ES1 in some embodiments.

The first end surface ES1 includes an upper surface U connected to (e.g., directly connected to) the top surface T and a lower surface L connected to (e.g., directly connected to) the bottom surface B, and the upper surface U and the lower surface L may meet to form the outermost edge P. In an embodiment, the upper surface U and the lower surface L may be curved surfaces (e.g., at least partially curved), such as concave curved surfaces. In an embodiment, the upper surface U may be a gentler curved surface than the lower surface L. For example, the upper surface U may have a concave curve that is more gentle than the concave curve of the lower surface L.

A protective layer PL may be positioned on the substrate layer BL (e.g., disposed directly thereon in the third direction DR3). The protective layer PL may include a resin. For example, in an embodiment the protective layer PL may not include a polymer film or glass and may be made of an optically transparent resin. The protective layer PL may be formed by coating a resin on the substrate layer BL. In an embodiment, a thickness of the protective layer PL in the third direction DR3 may be in a range of about 30 μm to about 80 μm.

The protective layer PL includes approximately four edges when viewed in a plan view, and an edge (e.g., an edge in a direction opposite to the second direction DR2) among the four edges that overlaps the second peripheral area PA2 may include a second end surface ES2. In an embodiment, the second end surface ES2 may be a curved surface connected to (e.g., directly connected to) the upper surface U of the substrate layer BL and may be a concave curved surface. In an embodiment, the outermost edge P of the first end surface ES1 may protrude outwardly beyond the second end surface ES2 of the protective layer PL (e.g., in a direction opposite to the second direction).

Referring to FIG. 4, a damping layer DL may be further included between the display panel DP and the protective film PF (e.g., in the third direction DR3). The damping layer DL may include a polymer film. For example, the damping layer DL may include polymer films such as polyethylene terephthalate (PET), polyimide (PI), triacetyl cellulose (TAC), and cyclic olefin polymer (COP). A thickness of the damping layer DL in the third direction DR3 may be in a range of about 15 μm to about 50 μm.

A first adhesive layer AL1 may be positioned between the display panel DP and the damping layer DL (e.g., in the third direction DR3), and a second adhesive layer AL2 may be positioned between the damping layer DL and the substrate layer BL (e.g., in the third direction DR3). For example, between the display panel DP and the damping layer DL, and between the damping layer DL and the substrate layer BL may be adhered through the first adhesive layer AL1 and the second adhesive layer AL2, respectively. In an embodiment, the first adhesive layer AL1 and the second adhesive layer AL2 may be a pressure sensitive adhesive (PSA) or an optically clear adhesive (OCA).

In the second peripheral area PA2, the protective film PF including each of the substrate layer BL and the protective layer PL may protrude (e.g., in a direction opposite to the second direction DR2) beyond the damping layer DL, the first adhesive layer AL1, and the second adhesive layer AL2.

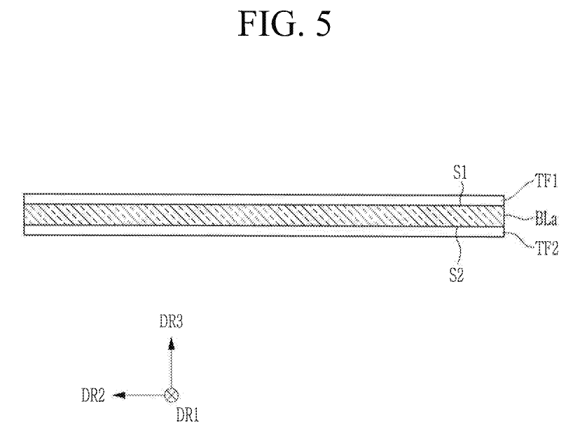

Referring to FIGS. 5-12 together with FIGS. 3 and 4, a manufacturing method of a display device according to an embodiment will be described. FIGS. 5-12 are cross-sectional views sequentially showing a manufacturing process of a display device according to an embodiment. Descriptions of the same configurations as in FIG. 4 will be omitted for economy of explanation.

Referring to FIG. 5, a first temporary film TF1 and a second temporary film TF2 may be attached to (e.g., disposed directly thereon) an extended substrate layer BLa. The extended substrate layer BLa may include a first surface S1 and a second surface S2 opposite to the first surface (e.g., in the third direction DR3). The first temporary film TF1 may be attached to the first surface S1 (e.g., disposed directly thereon in the third direction DR3), and the second temporary film TF2 may be attached to the second surface S2 (e.g., disposed directly thereon in a direction opposite to the third direction DR3). In an embodiment, a thickness of the extended substrate layer BLa (e.g., in the third direction DR3) may be in a range of about 20 μm to about 50 μm.

The extended substrate layer BLa may include glass or a polymer film. For example, in an embodiment the extended substrate layer BLa may include polymer films such as polyethylene terephthalate (PET), polyimide (PI), triacetyl cellulose (TAC), and cyclic olefin polymer (COP).

In an embodiment, the first temporary film TF1 and the second temporary film TF2 may be polymer films. In addition, the first temporary film TF1 and the second temporary film TF2 may be freely attached to and detached from the extended substrate layer BLa and may prevent damage to the extended substrate layer BLa.

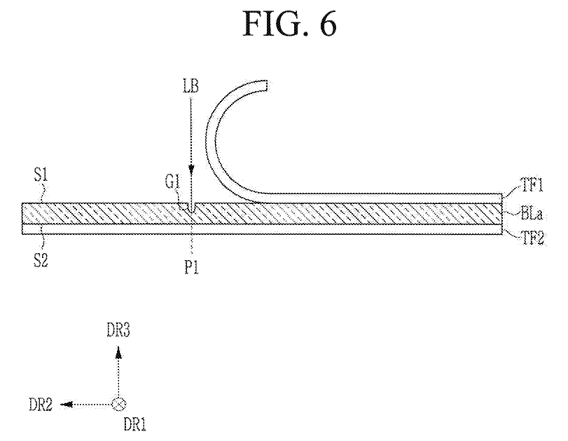

Referring to FIG. 6, a portion of the first temporary film TF1 may be detached, and a portion of the extended substrate layer BLa in the third direction DR3 may be cut at a first position P1 of the first surface S1. For example, in an embodiment a portion of the first temporary film TF1 may be detached to expose a portion of the first surface S1, and the extended substrate layer BLa may be cut with a laser LB from the exposed first surface S1 to form a first groove G1.

In an embodiment, the cutting at the first position P1 may be performed to a depth of a portion of the total thickness of the extended substrate layer BLa, for example, in a range of about 40% to 60% or about 50%, in the third direction DR3. For example, a depth of the first groove G1 may be in a range of about 40% to 60% or about 50% of the total thickness of the extended substrate layer BLa. In addition, cutting at the first position P1 may be performed by laser cutting along the first direction DR1. For example, the first groove G1 may extend in the first direction DR1.

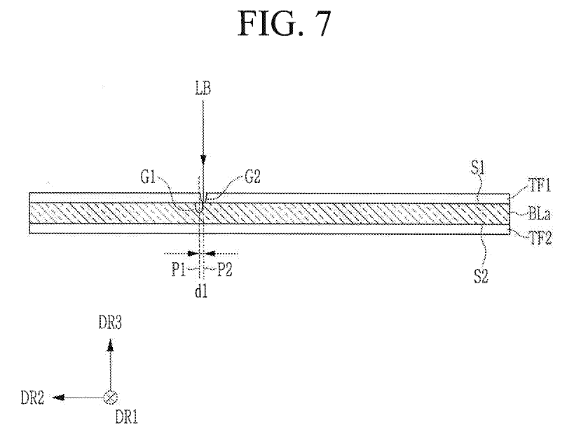

Referring to FIG. 7, in an embodiment the first temporary film TF1 detached in FIG. 6 may be reattached, and the first temporary film TF1 may be cut with a laser LB at a second position P2 adjacent to the first position P1 to form a second groove G2. In an embodiment, a separation distance d1 (e.g., in a direction opposite to the second direction DR2) between a center of the first position P1 and a center of the second position P2 may be in a range of about 10 μm to about 50 μm.

The cutting at the second position P2 may be performed to a depth in a range of about 90% to about 100% of the total thickness of the first temporary film TF1. For example, a depth of the second groove G2 may be in a range of about 90% to about 100% of the thickness of the first temporary film TF1. In addition, cutting at the second position P2 may be performed by laser cutting along the first direction DR1. For example, the second groove G2 may extend in the first direction DR1.

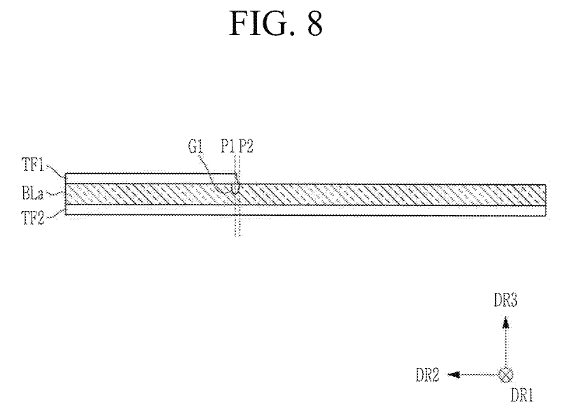

Referring to FIG. 8, a portion of the first temporary film TF1 may be removed. The first temporary film TF1 may be divided into two regions by the second groove G2 of FIG. 7. In an embodiment a portion of the first temporary film TF1 that does not overlap the first position P1 among the two regions may be removed to expose a portion of the first surface S1. For example, a portion of the first temporary film TF1 between the second position P2 and an end of the first temporary film TF1 (e.g., in a direction opposite to the second direction DR2) may be removed.

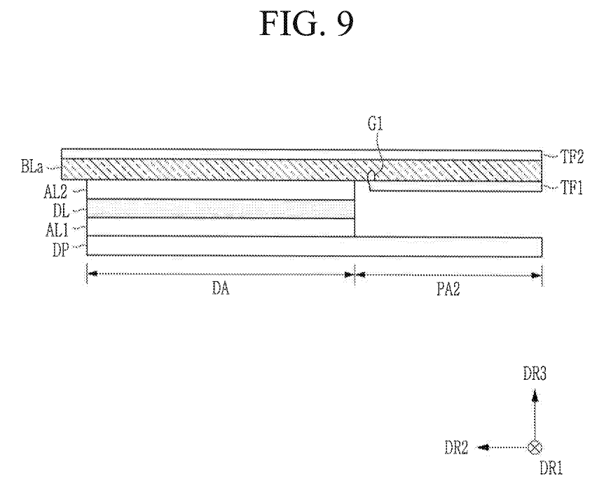

Referring to FIG. 9, an extended substrate layer BLa having the first temporary film TF1 and the second temporary film TF2 attached thereto may be attached on the display panel DP. The display panel DP and the first surface S1 may face each other, and the remaining first temporary film TF1 may overlap the second peripheral area PA2. In an embodiment, the extended substrate layer BLa may be attached on the display panel DP through an adhesive layer. In an embodiment shown in FIG. 9, the damping layer DL is positioned on the display panel DP, and the damping layer DL and the extended substrate layer BLa are attached to each other by the second adhesive layer AL2.

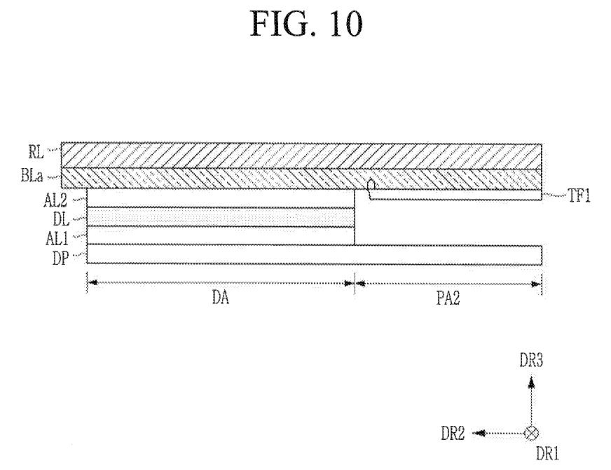

Referring to FIG. 10, the second temporary film TF2 may be removed and a resin layer RL may be coated on the second surface S2. In an embodiment, the resin layer RL may be formed by applying and curing an optically transparent resin on the second surface S2 of the extended substrate layer BLa. In an embodiment, the resin layer RL may be coated to a thickness (e.g., in the third direction DR3) in a range of about 30 μm to about 80 μm.

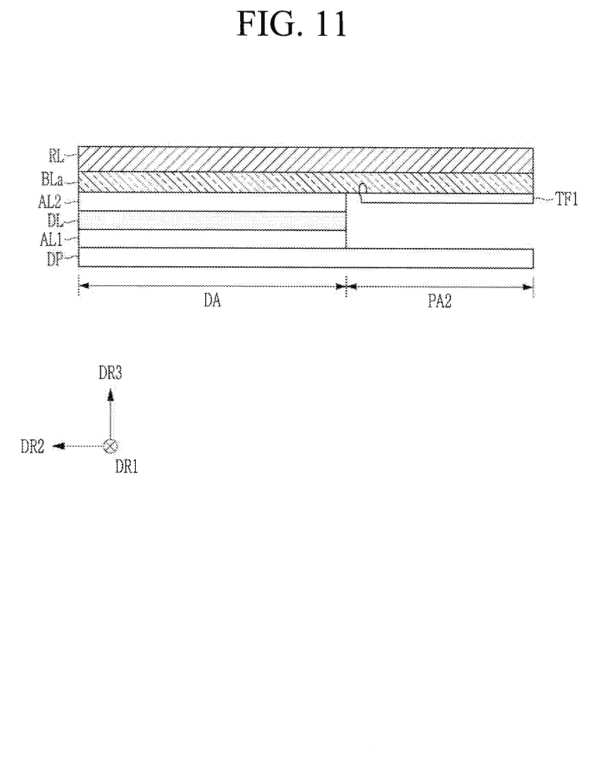

Referring to FIG. 11, the extended substrate layer BLa and the resin layer RL may be cut along an edge of the display panel DP, such as an edge in the second direction DR2. In an embodiment, the extended substrate layer BLa and the resin layer RL may be cut so that the edge of the display panel DP (e.g., in the second direction DR2) and the edges of the extended substrate layer BLa and the resin layer RL (e.g., in the second direction DR2) are aligned with each other.

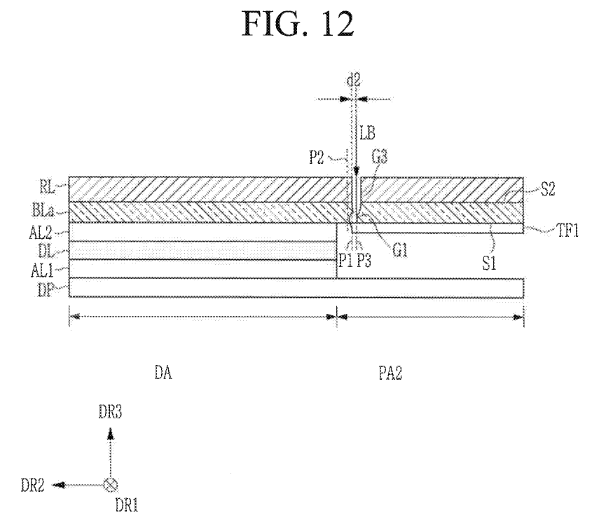

Referring to FIG. 12, the resin layer RL and the extended substrate layer BLa may be cut with a laser LB at a third position P3 adjacent to the first position P1 to form a third groove G3. In an embodiment, a separation distance d2 (e.g., in a direction opposite to the second direction DR2) between a center of the first position P1 and a center of the third position P3 may be in a range of about 1 μm to about 10 μm. The third position P3 may overlap the remaining first temporary film TF1. For example, the center of the third position P3 and the center of the second position P2 may be spaced apart in opposite directions from the center of the first position P1. The third position P3 may be positioned farthest from the display area DA (e.g., in a direction opposite to the second direction DR2) than the second position P2..

In an embodiment, the cutting at the third position P3 may be performed to a depth of an entire thickness (e.g., a total thickness) of the resin layer RL and a portion of the total thickness of the extended substrate layer BLa, for example, in a range of about 40% to about 60% or about 50%, in the third direction DR3. For example, a depth of the third groove G3 may be a sum of the total thickness of the resin layer RL and about 40% to about 60% or about 50% of the thickness of the extended substrate layer BLa. In addition, cutting at the third position P3 may be performed by laser cutting along the first direction DR1. For example, the third groove G3 may extend in the first direction DR1.

The third groove G3 may be adjacent to the first groove G1 and partially overlap the first groove G1. The first groove G1 is formed on the first surface S1 of the extended substrate layer BLa, and the third groove G3 may be formed to pass through the protective layer PL and the second surface S2 of the extended substrate layer BLa. The first groove G1 and the third groove G3 may meet each other in the extended substrate layer BLa. The first groove G1 and the third groove G3 may meet to form the outermost edge P of FIG. 4.

Due to the first groove G1 and the third groove G3, the resin layer RL and the extended substrate layer BLa may each be divided into two regions. Among the two regions, a portion of the resin layer RL, a portion of the extended substrate layer BLa, and the remaining first temporary film TF1 overlapping the second peripheral area PA2 may be removed to form the display device of FIG. 4.

Since cutting at the first position P1 was performed before cutting at the third position P3, cutting at the third position P3 does not cut the entire thickness of the extended substrate layer BLa. For example, since cutting was performed at the first surface S1 and the second surface S2 respectively without cutting the extended substrate layer BLa at once, the laser may not reach the display panel DP.

In addition, since the third position P3 and the first position P1 do not coincide with each other and a separation distance d2 between centers of the third position P3 and the first position P1 exists, the laser may be further prevented from reaching the display panel DP.

In addition, since the third position P3 overlaps the remaining first temporary film TF1, the first temporary film TF1 may prevent the laser from reaching the display panel DP. Therefore, damage to the display panel DP by the laser, particularly to the pad portion PP or the driving unit 50 positioned in the second peripheral area PA2, may be prevented.

In an embodiment, the cutting at the first position P1, the second position P2, and the third position P3 may be performed by laser cutting, and a wavelength band of the laser LB may be in a range of about 230 nm to about 260 nm, about 330 nm to about 360 nm, or about 10000 nm to about 11000 nm.

A display device according to an embodiment may be applied to various electronic devices. An electronic device according to an embodiment includes the above-described display device and may further include modules or devices having other additional functions in addition to the display device.

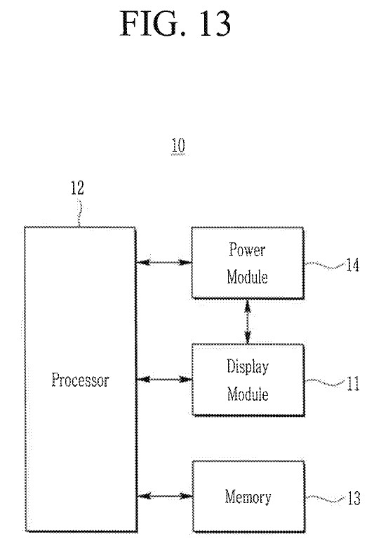

FIG. 13 is a block diagram of an electronic device according to an embodiment.

Referring to FIG. 13, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information desirable for operation of the processor 12 or the display module 11 may be stored in a memory 13. When the processor 12 executes an application stored in the memory 13, video data signals and/or input control signals are transmitted to the display module 11, and the display module 11 may process the provided signals to output video information through a display screen.

The power module 14 may include a power supply module such as a power adapter or a battery device and a power conversion module that converts power supplied by the power supply module to generate power desirable for operation of the electronic device 10.

At least one of the respective components of the above-described electronic device 10 may be included in the display device according to the above-described embodiments. In addition, some of the individual modules functionally included in one module may be included in the display device and others may be provided separately from the display device. For example, the display device may include the display module 11, and the processor 12, the memory 13, and the power module 14 may be provided in the form of other devices in the electronic device 10 rather than the display device.

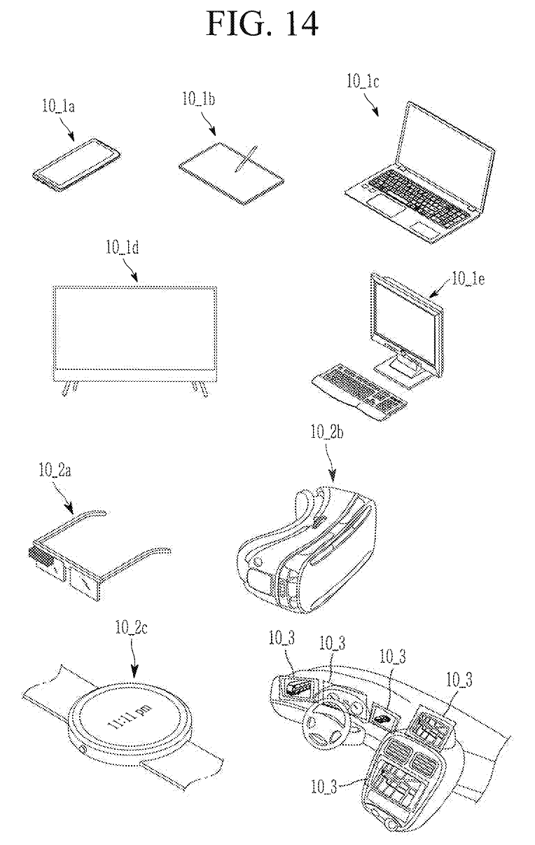

FIG. 14 is schematic diagrams of electronic devices according to various embodiments.

Although FIGS. 1-3 show the use of a display device in a smartphone, referring to FIG. 14, the display device may be applied to various other small-sized, medium-sized or large-sized electronic devices. Referring to FIG. 14, various electronic devices to which the display device according to embodiments is applied may include not only electronic devices for image display such as a smartphone 10_1a, a tablet PC 10_1b, a laptop 10_1c, a TV 10_1d, and a desktop monitor 10_1e, but also wearable electronic devices including a display module such as smart glasses 10_2a, a head mounted display 10_2b, and a smart watch 10_2c, and vehicle electronic devices 10_3 including a display module such as an instrument panel of a vehicle, a center fascia, a CID (Center Information Display) disposed on a dashboard, a room mirror display, and the like.

Although non-limiting embodiments of the present disclosure have been described in detail above, the scope of the present disclosure is not limited thereto, and various modifications and improvements by those skilled in the art using the basic concept of the present disclosure also belong to the scope of the present disclosure.

What is claimed is:

1. A display device comprising:
a display panel including a display area and a peripheral area including a pad portion;
a substrate layer disposed on the display panel, the substrate layer including an end surface overlapping the peripheral area; and
a protective layer disposed on the substrate layer,
wherein the protective layer includes a resin,
the end surface of the substrate layer overlapping the peripheral area has an outermost edge protruding outwardly beyond remaining portions of the end surface, and
the outermost edge is disposed at a middle of the end surface of the substrate layer in a thickness direction of the display panel.

2. The display device of claim 1, wherein:
the end surface of the substrate layer includes an upper surface and a lower surface;
the upper surface and the lower surface meet each other at the outermost edge; and
the upper surface and the lower surface are curved surfaces.

3. The display device of claim 2, wherein the curved surfaces of the upper surface and the lower surface are concave.

4. The display device of claim 2, wherein in the peripheral area, a top surface of the substrate layer connected to the upper surface protrudes beyond a bottom surface of the substrate layer connected to the lower surface.

5. The display device of claim 1, wherein in the peripheral area, the outermost edge of the substrate layer protrudes beyond an end surface of the protective layer.

6. The display device of claim 5, wherein the end surface of the protective layer overlapping the peripheral area is a curved surface.

7. The display device of claim 1, further comprising a damping layer disposed between the display panel and the substrate layer in the thickness direction of the display panel.

8. The display device of claim 7, wherein in the peripheral area, the substrate layer and the protective layer protrude beyond the damping layer.

9. The display device of claim 7, further comprising a first adhesive layer disposed between the display panel and the damping layer in the thickness direction of the display panel and a second adhesive layer disposed between the damping layer and the substrate layer in the thickness direction of the display panel.

10. A manufacturing method of a display device comprising:
preparing a display panel including a display area and a peripheral area including a pad portion;
preparing an extended substrate layer having a first temporary film attached to a first surface and a second temporary film attached to a second surface opposite to the first surface;
forming a first groove by detaching a portion of the first temporary film and cutting an exposed portion of the extended substrate layer in a thickness direction of the display device at a first position;
forming a second groove by reattaching the first temporary film and cutting the first temporary film at a second position adjacent to the first position;
removing a portion of the first temporary film that does not overlap the first position to expose a portion of the first surface;
attaching the extended substrate layer on the display panel such that the display panel and the first surface face each other;
removing the second temporary film and coating a resin layer on the second surface;
forming a third groove by cutting the resin layer and the extended substrate layer at a third position adjacent to the first position; and
removing a portion of the resin layer and a portion of the extended substrate layer and the first temporary film,
wherein the third position overlaps the first temporary film and the peripheral area.

11. The manufacturing method of claim 10, wherein:
the pad portion extends along a first direction in the peripheral area; and
the first groove, the second groove, and the third groove extend in the first direction.

12. The manufacturing method of claim 10, wherein a center of the second position and a center of the third position are respectively spaced apart in opposite directions from a center of the first position.

13. The manufacturing method of claim 12, wherein the second position is closer to the display area than the third position.

14. The manufacturing method of claim 13, wherein
a separation distance between the center of the first position and the center of the third position is in a range of about 1 μm to about 10 μm.

15. The manufacturing method of claim 13, wherein a separation distance between the center of the first position and the center of the second position is in a range of about 10 μm to about 50 μm.

16. The manufacturing method of claim 10, wherein a depth of the first groove is about 50% of a total thickness of the extended substrate layer.

17. The manufacturing method of claim 10, wherein a depth of the second groove is in a range of about 90% to about 100% of a total thickness of the first temporary film.

18. The manufacturing method of claim 10, wherein a depth of the third groove is a sum of a total thickness of the resin layer and about 50% of a total thickness of the extended substrate layer.

19. The manufacturing method of claim 10, further comprising cutting the extended substrate layer and the resin layer along an edge of the display panel.

20. An electronic device comprising:
a display device and a processor,
wherein the display device comprises:
a display panel including a display area and a peripheral area including a pad portion;
a substrate layer disposed on the display panel, the substrate layer including an end surface overlapping the peripheral area; and
a protective layer disposed on the substrate layer,
wherein the protective layer includes a resin,
the end surface of the substrate layer overlapping the peripheral area has an outermost edge protruding outwardly beyond remaining portions of the end surface, and
the outermost edge is disposed at a middle of the end surface of the substrate layer in a thickness direction of the display panel.
